(19) United States
(12) Patent Application Publication
(10) Pub. No.: US 2005/0253276 A1
(43) Pub. Date: Nov. 17, 2005

(54) Film for protecting mother glass for flat panel display and use thereof

(76) Inventors: Takeshi Yamanaka, Ibaraki-shi (JP); Minoru Hanaoka, Ibaraki-shi (JP); Yoshiki Kobayashi, Ibaraki-shi (JP); Hideaki Sakakura, Singapore (SG)

Correspondence Address: KNOBBE MARTENS OLSON & BEAR LLP, 2040 MAIN STREET, FOURTEENTH FLOOR, IRVINE, CA, 92614, US

(21) Appl. No.: 11/109,138

(22) Filed: Apr. 19, 2005

(30) Foreign Application Priority Data
Apr. 21, 2004 (JP) 2004-125553

(51) Int. Cl. H01L 23/48

(52) U.S. Cl. 257/778

(57) ABSTRACT

An object of the present invention is to provide a surface protecting film which dramatically improves an efficiency of transporting and storing a mother glass, has better peelability from an adherend when peeled without polluting a mother glass surface, and gives reinforcing effect, and use thereof, by using a pressure-sensitive adhesive protecting film. There is provided a film for protecting a mother glass for a flat panel display, characterized in that a rear side is unevenly-processed, and a pressure-sensitive adhesive side is smoother than a rear side.

### BACKGROUND OF THE INVENTION

1. Field of the Invention

The present invention relates to a film for protecting a mother glass for a flat panel display, which protects a surface of a mother glass used for manufacturing various display devices, and use thereof, and the present invention is useful as technique, particularly, for conveying a mother glass with protection.

2. Description of the Related Art

For manufacturing a flat panel display such as a liquid crystal display, a plasma display panel and an organic EL display, a glass substrate is used. A glass plate manufactured in a factory is distributed (conveyed) as a mother glass, and this is processed into the glass substrate. When a glass surface is flawed due to conveyance, storage, transport during shipping, and storage at customers of a mother glass, this becomes a cause for reduction in a yield, and adverse influence on quality, therefore, such a retaining form that glass surfaces are not contacted is usually adopted.

For this reason, regarding conveyance and storage of a mother glass, contacting to surfaces of mother glasses is prevented by forming a slit-like groove and fixing a mother glass in the groove one by one and, thereupon, a foamed molded article is mainly utilized.

Packaging with molded articles which are currently used are roughly classified into two kinds. One is a box-type packaging container, in which a groove is formed in a box, and sealing packaging is performed by fixing a mother glass therein, and closing it with a lid. The other is also called L-letter pad, and a groove for fixing a mother glass is formed inside an L-letter type foamed molded article, and uses a method of arranging this L-letter type foamed molded article on four corners of fundamental packaging number (e.g. 20)-bundled mother glasses, and fixing them by binding with a tape.

Any packaging state has advantages and defects and, for example, from a viewpoint of a clean degree, an L-letter type foamed molded article is advantageous in washing easiness, but from a viewpoint of stability and easy handling of packaging, a box-type is advantageous and, finally, both types were used for different purposes depending on the purpose and preference order of use by customers.

However, in recent years, with scale up of a flat panel display, scale up of a mother glass has been also demanded, it has become difficult to response to conveyance and storage of a scaled up mother glass, by the aforementioned packaging form. Specifically, clean washing of a large foamed molded article is difficult. In an L-letter type packaging material, since a vinyl bag is used for closing wrapping, it has become difficult to obtain the material having a controlled clean degree. In addition, also regarding a cost, in such the method, the number of glasses to be placed in a space per unit volume is small, and a piling efficiency is very low, leading to increase in a distribution cost. In addition, this foamed molded article itself approaches a limit of a foaming precision because of increase in a size. Alternatively, since a weight of a mother glass has been greatly increased, there is a problem on a strength and, for this reason, the article is reinforced with a metal bar. This becomes complicated and large scale and, as a result, the article is difficult to be available, and is becoming highly expensive.

In order to solve this problem, a conveying method of packaging a mother glass with a plastic film, and piling it has been proposed (see Japanese patent laid-open application publication JP-A No. 11-1205, JP-A No. 2003-237833, and JP-A No. 2003-273189). In particular, JP-A No. 11-1205 discloses prevention of occurrence of static electricity and scratch by subjecting a film surface to fine unevenly processing.

However, in a non-adhesive sheet or package like these methods, it is thought that rubbing with a mother glass and slippage easily occur with scale up of a mother glass. For this reason, even when an unevenly-processed film is used, there is a limit on prevention of occurrence of static electricity and scratch of a mother glass. In addition, in a non-adhesive sheet or package, a dust easily enters, so it is difficult to say that handling property of a mother glass and a laminate thereof is better, and there is little glass reinforcing effect.

On the other hand, a method of placing a plastic film (see JP-A No. 2003-226354) or a paper spacer between mother glasses has been performed. However, in this method, there has been feared a problem of pollution with an additive contained in a plastic film or a paper powder when a spacer is peeled from a mother glass.

### SUMMARY OF THE INVENTION

Accordingly, an object of the present invention is to provide a surface protecting film which dramatically improves an efficiency of transporting and storing a mother glass, has better peelability from an adherend when peeled without polluting a surface of a mother glass, and gives reinforcing effect, by adopting a pressure-sensitive protecting film, and use thereof.

The present inventors got the idea that a pressure-sensitive adhesive protecting film is produced using an unevenly-processed film substrate, but it was found that since a pressure-sensitive adhesive side easily becomes uneven due to influence of unevenly processing of a rear side by a normal method, a mother glass surface is polluted by adhesive remaining upon peeling. The following present invention solves such the problems, and attains the aforementioned object.

That is, a film for protecting a mother glass for a flat panel display of the present invention is characterized in that a rear side is unevenly-processed, and a pressure-sensitive adhesive side is smoother than the rear side. In the present invention, the “mother glass for a flat panel display” refers to a glass plate before processing into various products in the state where it can be distributed, and which is used for manufacturing a flat panel display. Examples of a fat panel display include display devices such as a liquid crystal display, a plasma display panel, and an organic EL display.

According to the protecting film of the present invention, since a pressure-sensitive adhesive protecting film is adopted, rubbing with a mother glass and slippage hardly occur, and a dust hardly enters, therefore, the film is effective in prevention of a scratch, and handling property of a mother glass and a laminate thereof becomes better. As a result, an efficiency of transporting and storing a mother glass can be dramatically improved. In addition, since physical reinforcing effect is also obtained, flexion of a mother glass can be prevented, and against scale up of a mother glass, flexion and cracking can be effectively prevented. Moreover, since a pressure-sensitive adhesive side is smoother than an unevenly-processed rear side, it becomes difficult to pollute a mother glass surface upon peeling while adherability is reduced by the rear side. Thereupon, due to reduction in adherability, handling property of a mother glass is further improved, and occurrence of static electricity can be also suppressed.

In the forgoing, it is preferable that the rear side is unevenly-processed in the state where the pressure-sensitive adhesive side is attached to a smooth surface, or a releasing side of a separator which is smoother than the rear side is attached to the pressure-sensitive adhesive side, or a pressure-sensitive adhesive layer forming the pressure-sensitive adhesive side is transferred from a substrate surface which is smoother than the rear side. Whereby, a pressure-sensitive adhesive side can be made to be smoother than an unevenly processed-rear side, and the aforementioned action and effect can be obtained more surely.

A process for manufacturing the film for protecting a mother glass for a flat panel display of the present invention comprises a step of unevenly-processing a rear side of the protecting film in the state where a pressure-sensitive adhesive side of the protecting film is attached to a mother glass. According to this process, since when a rear side is unevenly-processed, it hardly influences on a pressure-sensitive adhesive side of the protecting film, a pressure-sensitive adhesive side can be made to be smoother than an unevenly-processed rear side.

A process for manufacturing another film for protecting a mother glass for a flat panel display of the present invention comprises a step of attaching a releasing side of a separator, which is smoother than a rear side of the film in which the rear side is unevenly-processed, to a pressure-sensitive adhesive side of the film. According to this process, since a releasing side of a separator which is smoother than a rear side is attached to a pressure-sensitive adhesive side of the protecting film, a pressure-sensitive adhesive side can be made to be smoother than an unevenly processed rear side when a separator is peeled and used.

Another process for manufacturing a film for protecting a mother glass for a flat panel display of the present invention comprises a step of transferring a pressure-sensitive adhesive layer formed on a substrate surface which is smoother than a rear side of the film onto a film substrate in which at least a rear side is unevenly-processed. According to this process, since a pressure-sensitive adhesive layer formed on a substrate surface which is smoother than the rear side is transferred, unevenly processing of a rear side hardly influences on a pressure-sensitive adhesive side of the protecting film, and a pressure-sensitive adhesive side can be made to be smoother than an unevenly-processed rear side. As a result, the protecting film exerting the aforementioned action and effect can be manufactured.

On the one hand, a method of conveying a mother glass of the present invention is characterized in that a pressure-sensitive adhesive side of the aforementioned film for protecting a mother glass for a flat panel display is attached on at least one side of a mother glass, and a plurality of this are laminated to be conveyed. Since the method of conveying a mother glass of the present invention uses the protecting film of the present invention exerting the aforementioned action and effect, an effect of transporting and storing a mother glass is dramatically improved, peelability from an adherend becomes better when peeled without polluting a mother glass surface, and reinforcing effect is also obtained.

On the other hand, a mother glass with a protecting film of the present invention is such that a pressure-sensitive adhesive side of the film for protecting a mother glass for a flat panel display of the present invention is attached to at least one side of a mother glass. In addition, a mother glass laminate of the present invention is such that a pressure-sensitive adhesive side of the film for protecting a mother glass for a flat panel display of the present invention is attached to at least one side of a mother glass, and a plurality of this are laminated. Whereby, since the protecting film of the present invention exerting the aforementioned action and effect is attached, an efficiency of transporting and storing a mother glass is dramatically improved, peelability from an adherend becomes better when peeled without polluting a mother glass surface, and reinforcing effect is also obtained.

### BRIEF DESCRIPTION OF THE DRAWINGS

FIG. 1 is a cross-sectional view showing one example of a film for protecting a mother glass for a flat panel display of the present invention.

FIG. 2 is a cross-sectional view showing an example of a process for manufacturing a film for protecting a mother glass for a flat panel display of the present invention.

FIG. 3 is a cross-sectional view showing an example of a process for manufacturing a film for protecting a mother glass for a flat panel display of the present invention.

FIG. 4 is a cross-sectional view showing an example of a process for manufacturing a film for protecting a mother glass for a flat panel display of the present invention.

FIG. 5 is a cross-sectional view showing an example of the state of using a film for protecting a mother glass for a flat panel display of the present invention.

FIG. 6 is a cross-sectional view showing an example of the state of using a film for protecting a mother glass for a flat panel display of the present invention.

### DESCRIPTION OF THE PREFERRED EMBPDIMENTS

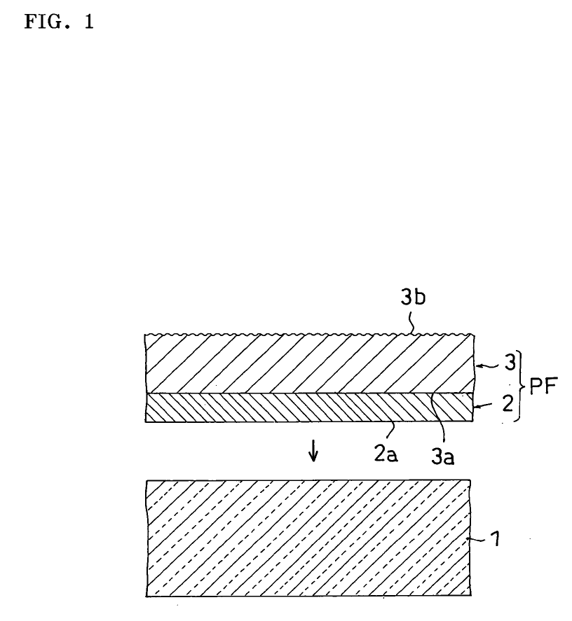

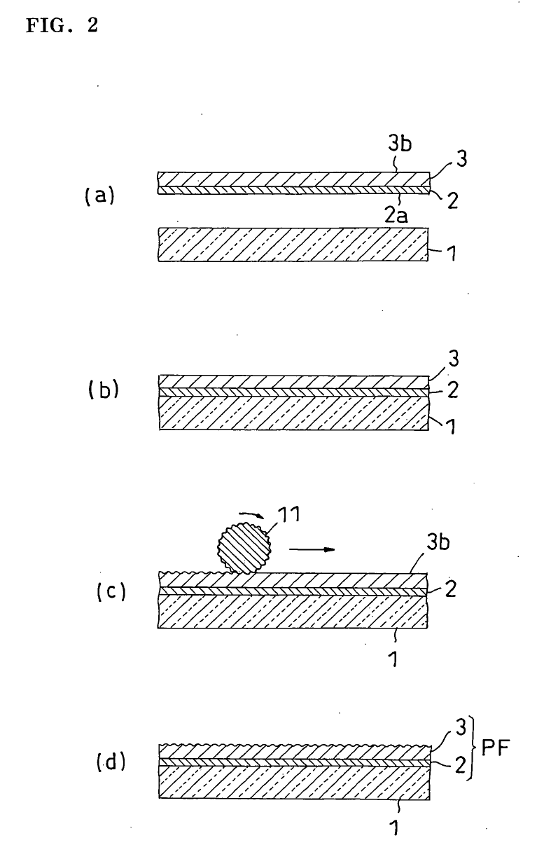

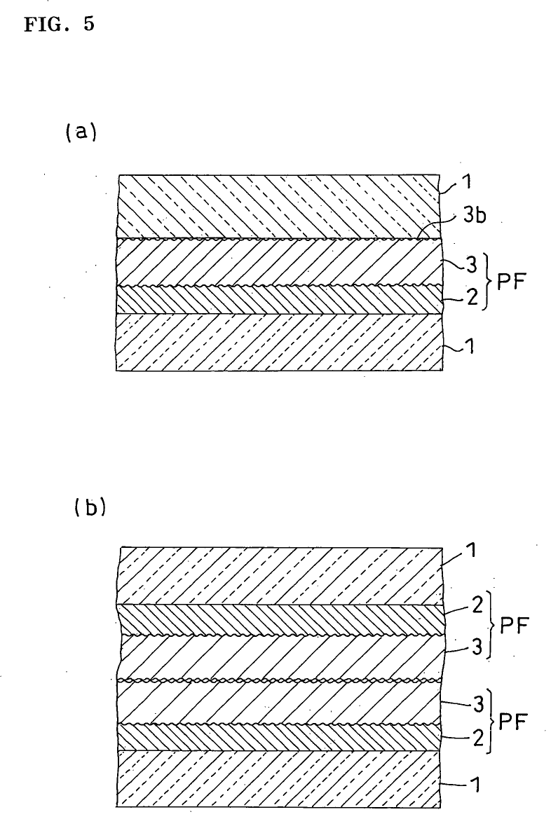

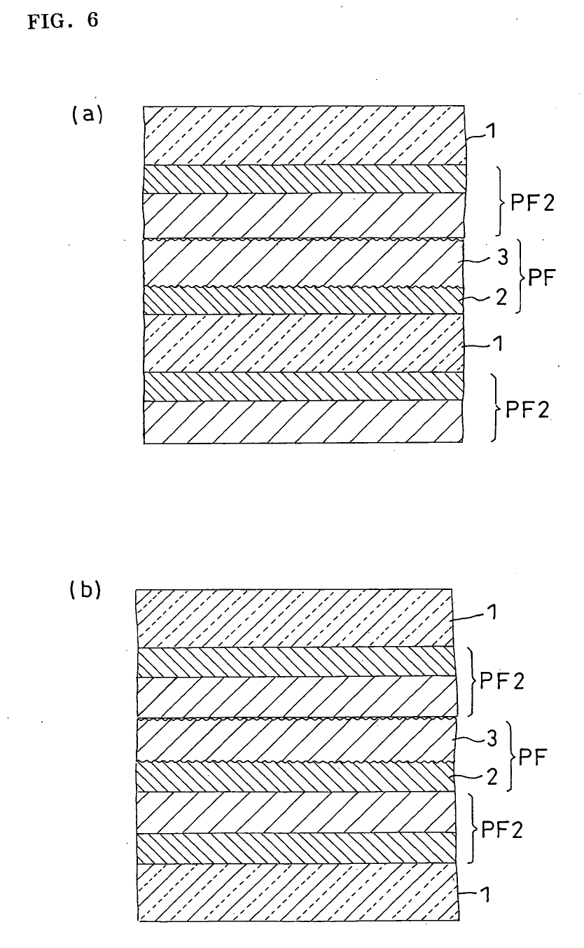

Embodiments of the present invention will be explained below by referring to the drawings. FIG. 1 is a cross-sectional view showing one example of a film for protecting a mother glass for a flat panel display of the present invention. FIGS. 2 to 4 are a cross-sectional view showing an example of a process for manufacturing a film for protecting a mother glass for a flat panel display of the present invention. FIGS. 5 to 6 are a cross-sectional view showing an example of the state of using a film for protecting a mother glass for a flat panel display of the present invention.

[Structure and Material of Protecting Film]

In the film for protecting a mother glass for a flat panel display of the present invention, a rear side is unevenly-processed. If a pressure-sensitive adhesive side is smoother than a rear side, the film may be monolayered, but as shown in FIG. 1, a structure having a pressure-sensitive adhesive layer 2 on one side of a film substrate 3 is preferable. The film for protecting a mother glass for a flat panel display is used by attaching a pressure-sensitive adhesive side 2a of a pressure-sensitive adhesive layer 2 to at least one side of a mother glass 1. It is preferable that this pressure-sensitive adhesive layer 2 comprises a crosslinked copolymer containing a (meth)acrylic acid ester monomer and a vinyl-based monomer having a functional group as a component.

Examples of the (meth)acrylic acid ester monomer include (meth)acrylic acid alkyl ester such as methyl acrylate, methyl methacrylate, ethyl acrylate, ethyl methacrylate, propyl acrylate, propyl methacrylate, butyl acrylate, butyl methacrylate, hexyl acrylate, hexyl methacrylate, octyl acrylate, octyl methacrylate, nonyl acrylate, nonyl methacrylate, dodecyl acrylate, and dodecyl methacrylate.

These alkyl parts may be straight or branched. These (meth)acrylic acid ester monomers may be used alone, or in a combination of two or more.

Examples of the vinyl-based monomer having a functional group include vinyl-based monomers having a carboxyl group such as acrylic acid, methacrylic acid, itaconic acid, crotonic acid, and maleic acid; vinyl-based monomers having a hydroxyl group such as 2-hydroxyethyl(meth)acrylate, 2-hydroxypropyl(meth)acrylate, and 2-hydroxyhexyl(meth)acrylate.

These vinyl-based monomers may be used alone, or in a combination of two or more.

A content of the vinyl-based monomer having a functional group is preferably 0.5 to 10 mol % in all monomers constituting a copolymer. When the content is less than 0.5 mol %, a copolymer cannot be sufficiently crosslinked with a crosslinking agent as described later, a solvent-insoluble fraction of a pressure-sensitive adhesive layer is decreased, and there is a tendency that adhesive remaining on a mother glass surface easily occurs upon peeling of a protecting film. On the other hand, when the content exceeds 10 mol %, there is a tendency that initial adhering property is inferior. From such a point of view, the content is preferably 1 to 8 mol %. In the present invention, other vinyl-based monomer containing no functional group may be used as a further copolymerization component.

A copolymer of the (meth)acrylic acid ester monomer and the vinyl-based monomer having a functional group are prepared by the previously known method. If necessary, a polymerization initiator can be used.

In the present invention, a glass transition temperature of the copolymer obtained by a Fox's equation is preferably −25 to −10° C., more preferably −23 to −12° C. When the glass transition temperature is lower than −25° C., an adhering strength becomes too high, and peeling from a mother glass becomes difficult. Conversely, when the glass transition temperature is higher than −10° C., an initial adhering strength of a pressure-sensitive adhesive layer obtained from such the copolymer at a normal temperature is deficient, and a role of function of protecting a mother glass cannot be exerted.
Fox's equation: 1/Tg=Σ(Wn/Tgn)
[wherein Tg(K) represents a glass transition temperature of a copolymer, Wn(−) represents a weight fraction of each monomer, Tgn(K) represents a glass transition temperature of a homopolymer of each monomer, and n represents a kind of each monomer]

Herein, a glass transition temperature Tgn(K) of a homopolymer of each monomer is known in various references. In the present invention, regarding each monomer of Table 1, a value of Table 1 is adopted. In the case of other monomers having no value in references or having inconsistent values in references, a value measured by general thermal analysis, for example, differential calorimetry or a dynamic viscoelasticity measuring method is adopted.

TABLE 1

| | | Homopolymer |
|---|---|---|
| Monomer | Abbreviation | Tg(K) |
| Methyl acrylate | MA | 281 |
| Ethyl acrylate | EA | 251 |
| Isopropyl acrylate | i-PA | 268 |
| n-Butyl acrylate | BA | 219 |
| 2-Ethylhexyl acrylate | 2EHA | 203 |
| Methyl methacrylate | MMA | 378 |
| Ethyl methacrylate | EMA | 338 |
| Isopropyl methacrylate | i-PMA | 354 |
| n-Butyl methacrylate | BMA | 293 |
| Isobutyl methacrylate | i-BMA | 340 |
| n-Hexyl methacrylate | HMA | 268 |
| Lauryl methacrylate | LMA | 208 |
| Acrylic acid | AA | 379 |
| Methacrylic acid | MAA | 403 |
| 2-Hydroxyethyl acrylate | 2HEA | 258 |
| Hydroxypropyl acrylate | HPA | 266 |
| 2-Hydroxyethyl methacrylate | 2HEMA | 328 |
| Hydroxypropyl methacrylate | HPMA | 299 |
| Maleic acid | IA | 403 |
| Acrylamide | AAm | 426 |
| Diacetoneacrylamide | DAAM | 338 |
| Glycidyl methacrylate | GMA | 314 |
| Styrene | St | 373 |
| Vinyl acetate | Vac | 303 |
| Acrylonitrile | AN | 373 |

In the present invention, a pressure-sensitive adhesive layer can be constructed by crosslinking the aforementioned copolymer with a crosslinking agent, and crosslinking is preferably performed by a reaction of a functional group of the vinyl-based monomer and a crosslinking agent.

The crosslinking agent is a compound having at least two or more groups which can react with a functional group of the vinyl-based monomer. Examples include polyfunctional isocyanate compounds such as trimethylolpropane tolylene diisocyanate, and methylene diisocyanate compound; polyglycidylamine compounds such as tetraglycidyl metaxylilenediamine, tetraglycidyl-1,3-bisaminomethylcyclohexane, tetraglycidyldiaminodiphenylmethane, triglycidyl p-aminophenol, diglycidylaniline, and diglycidyl o-toluidine. These crosslinking agents may be used alone, or in a combination of two or more.

An amount of the crosslinking agent to be blended depends on a content of a vinyl-based monomer having a functional group which is used in the copolymer, and is preferably 1 to 10 parts by weight, more preferably 2 to 8 parts by weight relative to 100 parts by weight of a copolymer. When the blending amount is less than 1 part by weight, a copolymer is not sufficiently crosslinked, and a solvent-insoluble fraction of a pressure-sensitive adhesive layer is decreased, so that there is a tendency that adhesive remaining easily occurs. Conversely, when the blending amount exceeds 10 parts by weight, there is a tendency that an initial adhering strength of a pressure-sensitive adhesive layer is deficient.

Further, the previously known various tackifier, and the previously known various additives such as an antistatic agent, a surface lubricant, a leveling agent, an antioxidant, a corrosion preventing agent, a light stabilizer, an ultraviolet absorbing agent, a polymerization inhibitor, a silane coupling agent, an inorganic or organic filler, and a powder, a particle and a foil such as a metal powder and a pigment can be appropriately added to a pressure-sensitive adhesive layer.

From a viewpoint of adherability to a glass surface, a thickness of a pressure-sensitive adhesive layer is preferably 0.1 to 30 μm, more preferably 0.5 to 20 μm.

As a film substrate used in the surface protecting film of the present invention, a plastic film prepared from the generally used polypropylene, high density polyethylene, low density polyethylene, medium density polyethylene, linear low density polyethylene, polyethylene terephthalate, and ethylene-α-olefin copolymer can be used, being not limiting.

A thickness of a film substrate is preferably 10 to 300 μm, more preferably 30 to 100 μm. When a thickness is in such the range, also in the case where used in a large size mother glass, handling property such as attaching and peeling of a protecting film, and reinforcing performance of a glass become better, and the effect of preventing a flaw at glass processing or conveyance is obtained.

A rear side of a film substrate is unevenly-processed by the method described later, and becomes to have a surface shape and a surface roughness depending on a processing method. The present invention is characterized in that a pressure-sensitive adhesive side of a pressure-sensitive adhesive layer is smoother than a rear side of a film substrate.

In the present invention, a smaller surface roughness Ra and a smaller surface roughness Rz are preferable. Specifically, it is preferable that a surface roughness Ra of a pressure-sensitive adhesive layer is 0.2 μm or smaller, or a surface roughness Rz is 1.0 μm or smaller. In the present invention, Ra and Rz are defined as values measured by the methods described later.

When a surface roughness Ra exceeds 0.2 μm, particulate pollutants tend to remain on a glass surface. Also when Rz exceeds 1.0 μm, there is a tendency that particulate pollutants remain on a glass surface. From such the point of view, it is desirable that Ra is preferably 0.1 μm or smaller, and Rz is preferably 0.5 μm or smaller.

[Process for Manufacturing Protecting Film]

The aforementioned protecting film can be suitably manufactured by the process of the present invention.

A process for manufacturing a film for protecting a mother glass for a flat panel display of the first invention comprises a step of unevenly-processing a rear side 3b of the protecting film in the state where a pressure-sensitive adhesive side 2a of the protecting film is attached to a mother glass 1 as shown in FIG. 2(a) to (d). The embodiment shown in FIG. 2 shows an example in which a pressure-sensitive adhesive layer 2 is formed on one side of a film substrate 3.

In the process of the first invention, first, as shown in FIG. 2 (a), a pressure-sensitive adhesive layer 2 is formed on a film substrate 3 before unevenly processing. As a method of forming a pressure-sensitive adhesive layer 2, the conventionally known method is adopted, but a method of coating a solution of a pressure-sensitive adhesive composition containing the aforementioned copolymer and a crosslinking agent, and then crosslinking the composition by treatment such as heating is preferable.

In this process, it is preferable to use a film substrate 3 having a smooth side to be coated. Examples of a method of coating a solution include roll coating, gravure coating, reverse coating, roll brushing, spray coating, and air knife coating methods.

Then, as shown in FIG. 2(b), a pressure-sensitive adhesive side 2a of the protecting film is attached to a mother glass 1.

Attachment of the protecting film can be performed by a method of attachment by pressing with a roller provided on a glass conveying line, a method of using a hand roller, or a method of using a pressing laminator.

Then, as shown in FIG. 2(c), a rear side 3b of a film substrate 3 is unevenly-processed in the attached state. Examples of a method of unevenly processing include, in addition to a method of embossing process using an embossing roll 11 or an embossing press mold, blast processing such as sand blast, a method of heating expansion using an expanding film, a method of roughening a surface with a polishing roll, laser processing, plasma processing, and sputtering processing. Among them, from a viewpoint of prevention of trash generation to maintain cleanability, processing with an embossing roll 11 or an embossing press is preferably used.

According to this process, a mother glass with a protecting film in which a pressure-sensitive adhesive side 2a of a protecting film PF of which a rear side 3b is unevenly-processed is attached to at least one side of a mother glass 1 is obtained. Thereupon, a rear side 3b is unevenly-processed in the state where a pressure-sensitive adhesive side 2a is attached to a smooth surface, and a pressure-sensitive adhesive side 2a becomes smoother than the rear side 3b.

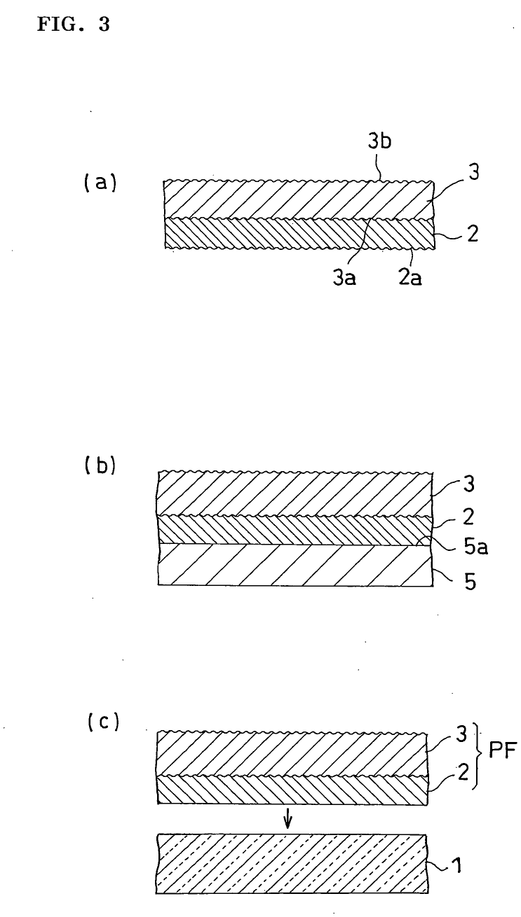

A process for manufacturing a film for protecting a mother glass for a flat panel display of the second invention comprises a step of attaching a releasing side 5a of a separator 5 which is smoother than a rear side 3b, to a pressure-sensitive adhesive side 2a of a protecting film in which the rear side 3b is unevenly-processed, as shown in FIG. 3(a) to (c).

In the process of the second invention, first, as shown in FIG. 3(a), a pressure-sensitive adhesive layer 2 is formed on a film substrate 3 in which a rear side 3b is unevenly-processed. Thereupon, unevenness easily occurs on a pressure-sensitive adhesive layer forming side 3a of a film substrate 3 due to influence of unevenly processing, and a pressure-sensitive adhesive side 2a of a pressure-sensitive adhesive layer 2 becomes to easily undergo the influence.

As a method of forming a pressure-sensitive adhesive layer 2, the conventionally known method is used, but a coating method which can reduce influence of unevenness of a film substrate 3 as much as possible is preferable. Examples of an unevenly-processed film substrate 3 include, in addition to the films obtained by the aforementioned methods, a film in which a surface is roughened by chemical treatment, and a film on which unevenness is formed by a fine particle included.

Then, as shown in FIG. 3(b), the releasing side 5a of a separator 5 which is smoother than the rear side 3b is attached to the pressure-sensitive adhesive side 2a of a protecting film. Attachment of the separator 5 can be performed by the aforementioned method. As substrate of a separator, a paper and a plastic film are exemplified but, from a viewpoint of excellent surface smoothness, a plastic film is suitably used.

Examples of a substrate film of a separator 5 include a polyethylene film, a polypropylene film, a polybutene film, a polybutadiene film, a polymethylpentene film, a polyvinyl chloride film, a vinyl chloride copolymer film, a polyethylene terephthalate film, a polybutylene terephthalate film, a polyurethane film, and an ethylene-vinyl acetate copolymer film. A pressure-sensitive adhesive layer attachment side of a separator has been subjected to treatment with a silicone releasing agent, a fluorine releasing agent, a long chain alkyl releasing agent or a fatty acid amide releasing agent. It is preferable that a releasing side 5a of a separator 5 is smoother, specifically, has the aforementioned surface roughness or smaller.

Then, as shown in FIG. 3(c), after a separator 5 is peeled, it is used by attaching to a mother glass 1. By attachment, a mother glass with a protecting film in which a pressure-sensitive adhesive side 2a of a protecting film PF in which a rear side 3b is unevenly-processed is attached to at least one side of a mother glass 1 is obtained. According to this process, a protecting film in which a releasing side 5a of a separator 5 which is smoother than a rear side 3b is attached to a pressure-sensitive side 2a is obtained, and a pressure-sensitive adhesive side 2a becomes smoother than a rear side 3b before attachment to a mother glass 1 and after attachment.

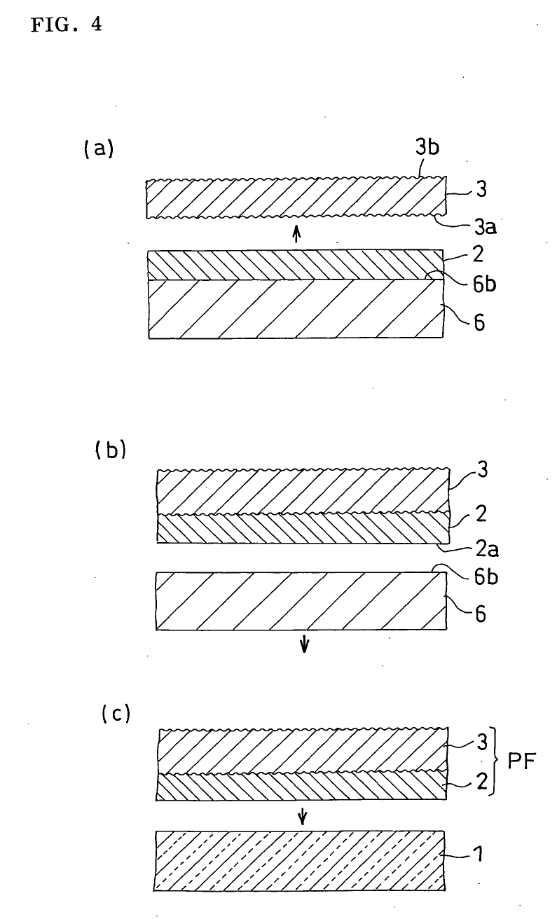

A process for manufacturing a film for protecting a mother glass for a flat panel display of the third invention comprises a step of transferring a pressure-sensitive adhesive layer 2 formed on a substrate surface 6b which is smoother than a rear side 3b onto a film substrate 3 in which at least the rear side 3b is unevenly-processed, as shown in FIG. 4(a) to (c).

In the process of the third invention, first, as shown in FIG. 4 (a), a pressure-sensitive adhesive layer 2 is formed on a surface 6b of a substrate 6 which is smoother than an unevenly-processed rear side 3b. As a method of forming a pressure-sensitive adhesive layer 2, the conventionally known method is adopted. As a smooth substrate 6, a metal belt or a metal roll having a releasing surface can be also used in addition to those exemplified as a separator 5.

Then, as shown in FIG. 4(b), a pressure-sensitive adhesive layer 2 formed on a substrate surface 6b is transferred onto an unevenly-processed film substrate 3. In transference of a pressure-sensitive adhesive layer 2, by the similar method to a method of attaching a separator 5 to a pressure-sensitive adhesive side 2a of a protecting film, attachment may be performed and, further, a substrate 6 may be peeled.

Then, as shown in FIG. 4(c), the film is used by attaching to a mother glass 1. By attachment, a mother glass with a protecting film in which a pressure-sensitive adhesive side 2a of a protecting film PH in which a rear side 3b is unevenly-processed is attached to at least one side of a mother glass 1 is obtained. In this process, in the state before attachment and after attachment, a pressure-sensitive adhesive side 2a becomes smoother than a rear side 3b. Alternatively, after transference of a pressure-sensitive adhesive layer 2, the protecting film may be stored with an attached separator 5.

[Method of using Protecting Film]

A method of conveying a mother glass of the present invention is such that a pressure-sensitive adhesive side 2a of a protecting film PF of the present invention is attached to at least one side of a mother glass 1, a plurality of this are laminated to be conveyed, as shown in FIGS. 5 to 6. In addition, a mother glass laminate of the present invention is such that a pressure-sensitive adhesive side 2a of a protecting film PF is attached to at least one side of a mother glass 1, and a plurality of this are laminated, as shown in FIGS. 5 to 6.

In the present invention, since an unevenly-processed protecting film PF is used, adherability between mother glasses with a protecting film attached thereto can be reduced to improve handling property of a mother glass. In addition, in the present invention, since a clean degree of a surface of a mother glass 1 is maintained by a protecting film, a paper spacer or other cushion material may intervene.

As a mother glass 1 for a flat panel display, glasses manufactured by a downflow method, a fusion method or a floating method can be suitably used. In addition, a surface roughness Rmax is preferably 30 nm or smaller, particularly preferably 10 nm or smaller. In addition, as a composition of a glass, an aluminosilicate glass, a soda aluminosilicate glass, a soda lime glass, and a borosilicate glass are suitable. In particular, even a mother glass used for manufacturing a display device such as a liquid crystal display, a plasma display panel, and an organic EL display can respond to scale up in recent years. The present invention is particularly effective for a mother glass having a thickness of 0.3 to 0.7 mm, and both of a long side and a short side of 1000 mm or larger.

Attachment of a protecting film can be performed by a method of attachment by pressing with a roller provided on a glass conveying line, a method of using a hand roller, or a method of using a pressing laminator.

In an example shown in FIG. 5(a), a protecting film PF is attached to one side of a mother glass 1, a rear side 3b of a protecting film PF is abutted against a non-attachment side of a mother glass 1 to be laminated, and a plurality of mother glasses 1 are laminated.

In an example shown in FIG. 5(b), a protecting film PF is attached to both sides of a mother glass 1 to be laminated, rear sides 3b of protecting films PF are abutted, and a plurality of mother glasses 1 are laminated.

In an example shown in FIG. 6(a), a protecting film PF in which a rear side 3b is unevenly-processed is attached to one side of a mother glass 1, and a protecting film PF2 in which a rear side is not unevenly-processed is attached to the other side, a rear side of a protecting film PF2 and a rear side 3b of a protecting film PF are abutted, and a plurality of mother glasses 1 are laminated.

In an example shown in FIG. 6(b), a protecting film PF2 in which a rear side is not unevenly-processed is attached to both sides of a mother glass 1 to be laminated, an unevenly-processed protecting film PF is further attached to its rear side, a rear side 3b of a protecting film PF and a rear side of a protecting film PF2 are abutted, and a plurality of mother glasses 1 are laminated.

The method of conveying a mother glass of the present invention is not different from the conventional method of conveying a mother glass except that a pressure-sensitive adhesive protecting film in which a rear side is unevenly-processed is attached, and any of the conventional methods can be adopted.

### EXAMPLES

Examples specifically showing a feature and the effect of the present invention will be explained below. Evaluation items in Examples were measured as follows:

1) Glass transition Temperature (Tg) of Copolymer

The temperature was obtained by the following Fox's equation:
Fox's equation: 1/Tg=Σ(Wn/Tgn)
[wherein Tg(K) represents a glass transition temperature of a copolymer, Wn(−) represents a weight fraction of each monomer, Tgn(K) represents a glass transition temperature of a homopolymer of each monomer, and n represents a kind of each monomer]. As Tgn(K), a value of Table 1 was adopted.

2) Initial Adhering Strength

A surface protecting film was attached to a mother glass for a liquid crystal substrate at a pressure of 8 kg/cm (in terms of linear pressure) and a rate of 0.3 m/min using a laminator. After allowing to stand at room temperature for 30 minutes, a surface protecting film was peeled at a tensile rate of 0.3 m/min and an angle of 180°, and a peeling force at that time was adopted as an initial adhering strength. A mother glass for a liquid crystal substrate was formed by a downdrawing method, and its surface roughness Rmax at polishing free was 10 nm or smaller. And, a composition of a glass was an alkali-free aluminosilicate glass.

3) Peeling Strength

A surface protecting film was attached to a mother glass for a liquid crystal substrate at a pressure of 8 kg/cm (in terms of linear pressure) and a rate of 0.3 m/min using a laminator. Thereafter, this was stored in a hot air circulating dryer at 50° C. for 3 days, and cooled to room temperature, and a surface protecting film was peeled at a tensile rate of 0.3 m/min and an angle of 180°, and a peeling force at that time was measured.

4) Measurement of Surface Roughness

In order to investigate a roughness of a pressure-sensitive adhesive surface of a surface protecting film, observation was performed using a surface shape measuring equipment. From measurement results, a center-line average surface roughness (Ra) and a ten-point average surface roughness (Rz) were obtained. A sample was cut into about 1 cm square, this was fixed on a glass plate with a double-sided tape, and subjected to vapor staining treatment with a 2% aqueous ruthenic acid solution at room temperature for 10 minutes, which was subjected to surface shape measurement.

As the surface shape measuring equipment, KLA-Tencor P-11 was used, and the measuring conditions were: measuring length; 2000 μm, scanning rate; 400 μm/sec, scanning time; 100 times(20 μm intervals), load; 3 mg.

5) Measurement of Particulate Residue on Adherend Surface

As an adherend, a mother glass for a liquid crystal substrate was used. To this were attached various surface protecting films, each of the protecting films was peeled under the same condition as that of 3), and the number of particles of 0.28 to 10 μm was measured.

As an analyzing apparatus, LS-5000 manufactured by Hitachi High-Tech Electronics Engineering Co., Ltd. was used. Almost all of particles were due to adhesive remaining.

### Example 1

68 Parts by weight of butyl acrylate, 29 parts by weight of methyl methacrylate, 3 parts by weight of 2-hydroxyethyl acrylate, 0.1 part by weight of 2,2′-azobis(2-amidinopropane) dichloride as a polymerization initiator, 1.5 parts by weight of sodium dodecylbenzenesulfonate as an emulsifying agent, and 100 parts by weight of water were placed into a reactor equipped with a cooling tube, a nitrogen introducing tube, a thermometer and a stirring device, emulsion polymerization was performed at 80° C. for 5 hours, and a pH was adjusted to 7.0 with 15% by weight of aqueous ammonia to obtain a copolymer emulsion having 50% by weight of a solid content.

This emulsion was salted out with hydrochloric acid, washed with water, and dried to obtain an acryl copolymer. This acryl copolymer was dissolved in toluene, and to this solution was added 3 parts by weight of trimethylolpropane tolylene diisocyanate relative to 100 parts by weight of a solid content of an acryl copolymer, followed by mixing to obtain a pressure-sensitive adhesive composition solution.

This solution was coated on a releasing-treated side of a PET film having a surface roughness Ra=0.01 μm and Rz=0.12 μm, and a thickness of 50 μm which had been subjected to releasing treatment, so that a coated film after drying became 10 μm, this was dried in a drier at 80° C. for 3 minutes to form a pressure-sensitive adhesive layer. To this was attached a polyolefin film having a surface roughness Ra=0.06 μm and Rz=0.33 μm, and a thickness of 40 μm to obtain a surface protecting film.

### Comparative Example 1

According to the entirely same manner as that of Example 1, a pressure-sensitive adhesive composition solution was prepared. This solution was coated on a polyolefin film having a surface roughness Ra=0.06 μm and Rz=0.33 μm, and a thickness of 40 μm, so that a coated film after drying became 10 μm, this was dried in a drier at 80° C. for 3 minutes to form a pressure-sensitive adhesive layer. To this was attached a blend film of polyethylene and polypropylene having a surface roughness Ra=0.06 μm and Rz=0.33 μm, to obtain a surface protecting film.

### Comparative Example 2

According to the entirely same manner as that of Example 1, a pressure-sensitive adhesive composition solution was prepared. This solution was coated on a blend film of polyethylene and polypropylene having a surface roughness Ra=0.06 μm and Rz=0.33 μm, and a thickness of 40 μm with a roll coater so that a coated film after drying became 10 μm, and this was dried in a drier at 80° C. at a coating rate of 40 m/min, and wound up to obtain a surface protecting film.

Evaluation results of the aforementioned surface protecting films are shown in Table 2.

TABLE 2

| | | | Comp. | Comp. |
|---|---|---|---|---|
| | | Ex. 1 | Example 1 | Example 2 |
| Glass transition temperature (° C.) of | | −22.3 | −22.3 | −22.3 |
| copolymer | | | | |
| Initial adhering strength (N/20 mm) | | 0.34 | 0.11 | 0.10 |
| Peeling strength (N/20 mm) | | 0.12 | 0.01 | 0.01 |
| Measurement of surface | Ra | 0.01 | 0.20 | 0.22 |
| roughness (μm) | Rz | 0.12 | 1.14 | 1.16 |
| Measurement of particulate | Number/ | 398 | 4738 | 5230 |
| residues on adherend | 78.5 cm² | | | |
| surface | | | | |

As shown by results of Table 2, by comparison of Example 1 and Comparative Example 1, it is found that as a surface roughness grows smaller, the number of particulate residues becomes smaller upon peeling and, at the same time, it is found that use of transferring method or smooth separator becomes effective. In addition, from results of Comparative Example 2, it is found that unevenness of a rear side of a film substrate is transferred, and a pressure-sensitive adhesive side becomes irregular and, as a result, the number of particulate residues is increased at peeling.

In Examples of the present invention, since occurrence of particles can be prevented when a protecting film is peeled from a mother glass for a liquid crystal substrate, a yield of manufacturing a liquid crystal panel could be increased. In particular, since occurrence of particles of 0.5 μm or larger could be prevented, remarkable improvement was possible as compared with the conventional films.

1. A film for protecting a mother glass for a flat panel display, wherein a rear side is unevenly-processed, and a pressure-sensitive adhesive side is smoother than the rear side.

2. The film for protecting a mother glass for a flat panel display according to claim 1, wherein the rear side is unevenly-processed in the state where the pressure-sensitive adhesive side is attached to a smooth surface.

3. The film for protecting a mother glass for a flat panel display according to claim 1, wherein a releasing side of a separator which is smoother than the rear side is attached to a pressure-sensitive adhesive side.

4. The film for protecting a mother glass for a flat panel display according to claim 1, wherein a pressure-sensitive adhesive layer forming the pressure-sensitive adhesive side is transferred from a substrate surface which is smoother than the rear side.

5. A process for manufacturing a film for protecting a mother glass for a flat panel display, comprising a step of unevenly-processing a rear side of a protecting film in the state where a pressure-sensitive adhesive side of the protecting film is attached to a mother glass for a flat panel display.

6. A process for manufacturing a film for protecting a mother glass for a flat panel display, comprising a step of attaching a releasing side of a separator, which is smoother than a rear side of the film in which the rear side is unevenly-processed, to a pressure-sensitive adhesive side of the film.

7. A process for manufacturing a film for protecting a mother glass for a flat panel display, comprising a step of transferring a pressure-sensitive adhesive layer formed on a substrate surface which is smoother than a rear side of the film, onto a film substrate in which at least the rear side is unevenly-processed.

8. A method of conveying a mother glass, comprising attaching a pressure-sensitive adhesive side of a film for protecting a mother glass for a flat panel display as defined in claim 1 to at least one side of a mother glass for a flat panel display, and laminating a plurality of this to be conveyed.

9. A mother glass for a flat panel display with a protecting film, wherein a pressure-sensitive adhesive side of a film for protecting a mother glass for a flat panel display as defined in claim 1 is attached to at least one side of a mother glass for a flat panel display.

10. A mother glass laminate for a flat panel display, wherein a pressure-sensitive adhesive side of a film for protecting a mother glass for a flat panel display as defined in claim 1 is attached to at least one side of a mother glass for a flat panel display, and a plurality of this are laminated.

11. A method of conveying a mother glass, comprising attaching a pressure-sensitive adhesive side of a film for protecting a mother glass for a flat panel display as defined in claim 2 to at least one side of a mother glass for a flat panel display, and laminating a plurality of this to be conveyed.

12. A method of conveying a mother glass, comprising attaching a pressure-sensitive adhesive side of a film for protecting a mother glass for a flat panel display as defined in claim 3 to at least one side of a mother glass for a flat panel display, and laminating a plurality of this to be conveyed.

13. A method of conveying a mother glass, comprising attaching a pressure-sensitive adhesive side of a film for protecting a mother glass for a flat panel display as defined in claim 4 to at least one side of a mother glass for a flat panel display, and laminating a plurality of this to be conveyed.

14. A mother glass for a flat panel display with a protecting film, wherein a pressure-sensitive adhesive side of a film for protecting a mother glass for a flat panel display as defined in claim 2 is attached to at least one side of a mother glass for a flat panel display.

15. A mother glass for a flat panel display with a protecting film, wherein a pressure-sensitive adhesive side of a film for protecting a mother glass for a flat panel display as defined in claim 3 is attached to at least one side of a mother glass for a flat panel display.

16. A mother glass for a flat panel display with a protecting film, wherein a pressure-sensitive adhesive side of a film for protecting a mother glass for a flat panel display as defined in claim 4 is attached to at least one side of a mother glass for a flat panel display.

17. A mother glass laminate for a flat panel display, wherein a pressure-sensitive adhesive side of a film for protecting a mother glass for a flat panel display as defined in claim 2 is attached to at least one side of a mother glass for a flat panel display, and a plurality of this are laminated.

18. A mother glass laminate for a flat panel display, wherein a pressure-sensitive adhesive side of a film for protecting a mother glass for a flat panel display as defined in claim 3 is attached to at least one side of a mother glass for a flat panel display, and a plurality of this are laminated.

19. A mother glass laminate for a flat panel display, wherein a pressure-sensitive adhesive side of a film for protecting a mother glass for a flat panel display as defined in claim 4 is attached to at least one side of a mother glass for a flat panel display, and a plurality of this are laminated.

20. A protective film for protecting a mother glass for a flat panel display, comprising:
a film substrate having a rear side and an adhesive side, said rear side having an unevenly processed surface; and
a pressure-sensitive adhesive layer formed on the adhesive side of the film substrate and having a surface which is smoother than the rear side surface and has a center-line average surface roughness (Ra) of 0.2 μm or smaller and a ten-point average surface roughness (Rz) of 1.0 μm or smaller.

21. The protective film according to claim 20, wherein Ra is 0.1 μm or smaller, and Rz is 0.5 μm or smaller.

22. The protective film according to claim 20, wherein the pressure-sensitive adhesive layer comprises a crosslinked copolymer constituted by a (meth)acrylic acid ester monomer and a vinyl-based monomer having a functional group as a component.

23. The protective film according to claim 22, wherein the copolymer has a glass transition temperature defined by Fox's equation of −25 to −10° C.:
Fox's equation: 1/Tg=Σ(Wn/Tgn)
wherein Tg (K) represents a glass transition temperature of the copolymer, Wn (−) represents a weight fraction of each monomer, Tgn (K) represents a glass transition temperature of a homopolymer of each monomer, and n represents a kind of each monomer.

24. The protective film according to claim 20, wherein the film substrate has a thickness of 10-300 μm, and the pressure-sensitive adhesive layer has a thickness of 0.1-30 μm.

25. A method of conveying mother glasses using the protective film claimed in claim 20, comprising:
providing multiple mother glass for flat panel displays;
attaching the pressure-sensitive adhesive side of the protective film to at least one side of each mother glass;
stacking the protective film-attached mother glasses for transportation; and
removing the protective film from each mother glass for use.
